(19) United States
(12) Patent Application Publication
(10) Pub. No.: US 2005/0243522 A1
(43) Pub. Date: Nov. 3, 2005

(54) Combined packaging and storage apparatus having added functionality

(75) Inventors: Ryan M. Nilsen, Pompano Beach, FL (US); James L. Tracy, Coral Springs, FL (US); Nitin B. Desai, Coral Springs, FL (US); James A. Zollo, Weston, FL (US)

Correspondence Address: AKERMAN SENTERFITT, P.O. BOX 3188, WEST PALM BEACH, FL, 33402-3188, US

(73) Assignee: Motorola, Inc., Schaumburg, IL (US)

(21) Appl. No.: 10/837,418

(22) Filed: Apr. 30, 2004

(51) Int. Cl. G06F 15/16; H05K 7/20

(52) U.S. Cl. 361/716

(57) ABSTRACT

A multi-purpose product packaging (100, 200) for an electronic host product (250) having its own casing can include an apparatus casing (110, 210) for removably and substantially encasing the electronic host product, circuitry (240) within the apparatus casing for providing at least one function to the electronic host product, and an interface (255) on the apparatus casing for enabling the at least one function to operate in conjunction with the electronic product. The apparatus casing can be made of recyclable products and the interface can form a portion of the circuitry within the apparatus casing. In one embodiment, the electronic host device can be a phone and the circuitry can provide any number of functions including the function of charging a power source within the phone.

### CROSS REFERENCE TO RELATED APPLICATIONS

Not Applicable.

### FIELD OF THE INVENTION

This invention relates to the field of product packaging, and more particularly, to product packaging having added functionality.

### BACKGROUND

Many products are sold using similar packaging and advertising structures. In a typical arrangement, the actual product to be sold is enclosed within a paper or plastic package which displays pictures of the product and brand logos. Inside the package, a product, and in particular electronic devices, can be separated into multiple product parts, where each part is individually enclosed in additional packaging material. These individual product parts will often require some assembly to produce a fully functional and operable product. Once the individual product parts have been removed from their packaging and assembled, the entire product packaging, including items such as cardboard boxes, foam insulation, Styrofoam, bubble-wrap, shrink-wrapping, twist-ties, plastic bags and even product manuals, are discarded. When viewed from the number of products that are sold, the amount of discarded material can be substantial. In one specific example, a cordless phone system can come in external packaging made of cardboard and additional packaging for a handset, a charging base, power cords, telephone cords, batteries and the like. All the packaging associated with the cordless phone system typically gets thrown away and is usually not recycled.

Although the technology and innovation in product packaging has remained relatively stagnant, the technology for designing and manufacturing electronic devices has improved exponentially over the past few decades. Most electronic devices, ranging from computers to mobile phones, have become smaller, faster, cheaper, and more accessible. As the devices have improved, some of their predecessors have become outdated and some can even be considered obsolete. Users tend to stop using the older devices in favor of the latest technology or the newest trends. Therefore, the older devices usually end up in attics, closets, basements, garages and landfills. Once in the landfill, these devices can leach potentially toxic materials, particularly those with lead power supplies. These discarded electronic products pose a formidable environmental challenge to our communities.

The combined accumulation of product packaging for electronic devices and the outdated electronic devices themselves creates a substantial portion of the waste that society would rather simply bury. Instead of burying this waste, effective measures should be undertaken to reduce the amount of waste produced and to make recyclable the products and components that may eventually become outdated or obsolete. Furthermore, external product packaging usually serves no other purpose other than the ability to merchandise and to ship the product safely to the end-user. No additional functionality is typically provided by such product packaging.

### SUMMARY OF THE INVENTION

Embodiments in accordance with the present invention provide an enclosure or outer casing for an electronic host product used for marketing, shipping and storage of the electronic host product. The enclosure casing can optionally be made of recyclable materials. The enclosure casing can also provide additional functionality useful for operating the electronic host product. The additional functionality can be for any number of functions such as for charging the power source of the electronic host product, or providing projected images from within the host product, but such additional functionality is certainly not limited to charging batteries, or projecting images

In one aspect of the inventive arrangements, an integrated packaging and storage apparatus for electronic host devices is provided. The apparatus can include a casing constructed and arranged to store an electronic host device having its own device housing or casing where the apparatus casing provides product packaging used in the process of selling the electronic host device and also serves as a storage container. The integrated packaging and storage apparatus can also include any number of functional components or devices such as a charging device within the apparatus casing. The charging device may include a wireless (inductive) charging device and/or a charging device with a cord or a retractable cord in yet another alternative. The apparatus casing can include electronic device components communicably coupled to the electronic host device. Further, a portion of the apparatus casing may include recycled materials.

In one embodiment, the apparatus casing can include a cover portion and a holding portion. The cover portion may be removably coupled to the holding portion, slidably coupled to the holding portion, snappably coupled to the holding portion, and/or hingably coupled to the holding portion. Therefore, the cover portion may be coupled to the holding portion by any combination of a removable coupling, a slidable coupling, a snappable coupling, and a hingeable coupling.

In another arrangement, the cover portion and/or the holding portion of the apparatus casing can include an elongated channel allowing relative sliding movement. Further, the elongated channel may include stops. The cover portion may also support the holding portion in a standing position. Additionally, the holding portion may include separate compartments constructed and arranged to hold electronic device accessories. The apparatus casing can also include belt clip engagement structure where the engagement structure may be constructed and arranged so that a belt clip attaches to the apparatus casing using the engagement structure.

In still another aspect of the inventive arrangements, a multi-purpose product packaging for an electronic host product having its own casing can include a apparatus casing for removably and substantially encasing the electronic host product, plus circuitry within the housing for providing at least one function to the electronic product, and an interface integrated with the housing for enabling the at least one function to operate in conjunction with the electronic host product. The apparatus casing can be made of recyclable products and the interface can couple to a portion of the circuitry within the apparatus casing. In a particular embodiment, the electronic host device can be a mobile phone and the circuitry can provide the function of charging a power source within the phone. In an alternate or additional embodiment, the electronic host device can be a PDA, and the circuitry can provide for a projected display image function. Note that the concepts herein are not limited to a phone or the function of charging, but can be applicable to most electronic products and functions associated with such products.

In yet another aspect of the inventive arrangements, a multi-purpose product packaging for an electronic host product having its own casing can include a storage medium within the removable apparatus casing having an instruction manual stored electronically therein and an abbreviated instruction manual presented on a surface of the data storage medium. The abbreviated instruction manual can be a quickstart guide printed on the surface of the storage medium which is removable from the removable apparatus casing.

The above features and advantages of the present invention will be better understood with reference to the following figures and detailed description. It should be appreciated that the particular devices and methods illustrating the present invention are exemplary only and not to be regarded as limitations of the present invention.

### BRIEF DESCRIPTION OF THE DRAWINGS

There are presently shown in the drawings embodiments which are presently preferred, it being understood, however, that the invention is not limited to the precise arrangements and instrumentalities shown.

FIG. 1 is a perspective view of one embodiment of a packaging and storage apparatus in accordance with the inventive arrangements.

FIG. 2 is another view of FIG. 1. illustrating a slidable relationship between a holder and a cover of the packaging and storage apparatus.

FIG. 3 is another perspective view in a face down orientation of the packaging and storage apparatus of FIG. 1 illustrating a charging device arranged in accordance with an embodiment of the present invention.

FIG. 4 is another perspective view of FIG. 1 illustrating the packaging and storage apparatus in a standing position in accordance with an embodiment of the present invention.

FIG. 5 is a perspective view of an embodiment of a multi-purpose product packaging for an electronic host product in accordance with the inventive arrangements.

FIG. 6 is a perspective view of another embodiment of a multi-purpose product packaging for an electronic host product in accordance with the inventive arrangements.

FIG. 7 is a side view of the embodiment shown in FIG. 6.

### DETAILED DESCRIPTION

The present invention provides a multi-purpose apparatus for use as product packaging and a storage apparatus. As understood herein, the product packaging and storage apparatus or the multi-purpose apparatus can be referred to as a “casing” that encases or substantially encases an electronic host product. Such a casing eliminates the waste associated with typical product packaging for an electronic host product and can help reduce the amount of materials sent to landfills and other dumpsites. Still further, as the casing can include circuitry such as integrated electronic device components typically included in a separate accessory device for the electronic host product, the casing along with the integrated electronic device components provides a compact unit having the requisite level of functionality between the casing and the electronic host product.

The casing with the added functionality herein can replace separate devices each possibly having their own casings. If a separate battery charging device serves as the separate accessory device, now, in accordance with an embodiment of the invention, the casing for the electronic host product incorporates the accessory device. Note, other functionality typically reserved for the electronic host device can alternatively be incorporated or integrated into the casing. Functions that are infrequently used or create other impracticalities in an electronic host product can probably serve the users of such electronic host products better by being incorporated in the casing. In even further attempts to reduce waste, the casing and/or the electronic host product can be made from or partially made from recyclable materials which would enable the reuse of existing products to make new products.

As used herein, “integrated” refers to a collection of distinct elements or components that have been built into one unit which can be removable in certain embodiments. Also, as noted above, the product packaging and storage apparatus (casing) can include functionality used occasionally or infrequently by the user which might otherwise cause the electronic device alone to be impractically large, bulky or unmanageable if it were fully integrated with the electronic device. In a certain respect, embodiments herein provide de-convergence of certain functionality from the electronic device into a separate enclosure that also happens to serve as product packaging for the electronic host product. Nonetheless, the electronic host device and the casing combined form a unit that operates cooperatively.

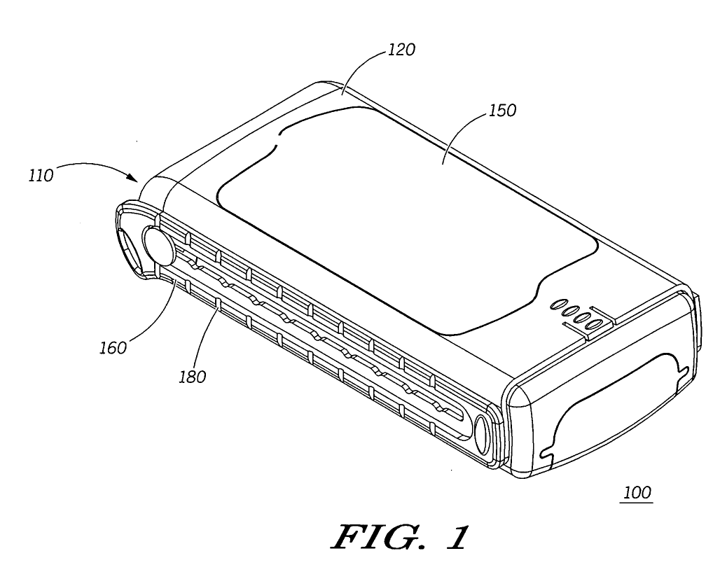

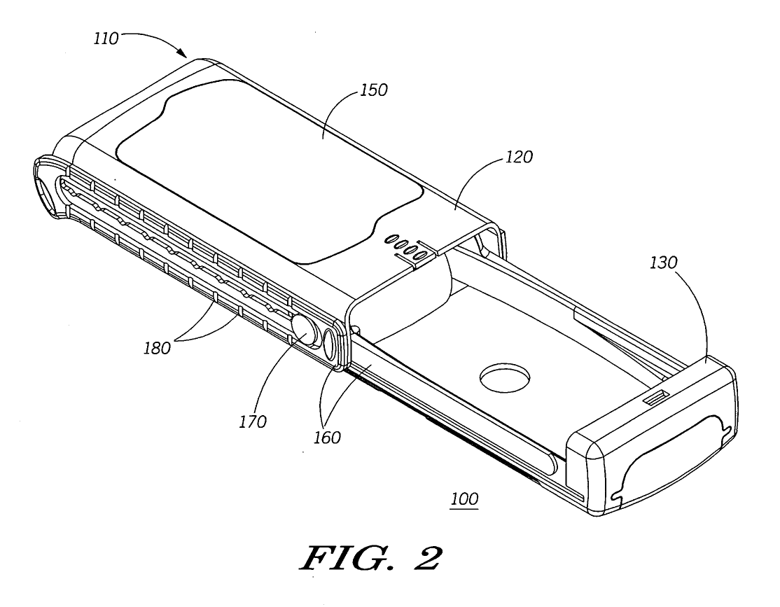

An exemplary embodiment of a packaging and storage apparatus 100 for electronic devices is shown from various viewpoints in FIGS. 1-3. The apparatus 100 can include a casing 110. The casing 110 can be constructed and arranged to store various host products. As electronic (host) devices or products are produced in a variety of shapes and sizes, the shape, and particularly the internal contours of the casing 110, is not limited. The shape of the casing 110 can be designed in accordance with the size and shape of the particular electronic devices. For instance, the internal contours of the cover portion 120 and/or the holding portion 130 (See FIG. 2) can form generally a silhouette of the shape of the electronic host device so that the electronic host device fits snuggly in the holding portion 130 and movement is limited in the casing 110. Limited or restricted movement can help prevent damage during product shipping and during user storage, particularly when the casing 110 is used during physical activities, such as jogging, walking, rock climbing, and the like. To that end, it should be noted that the interior of the casing 110 can include materials, such as rubber or foam, for absorbing shock to further prevent movement damage.

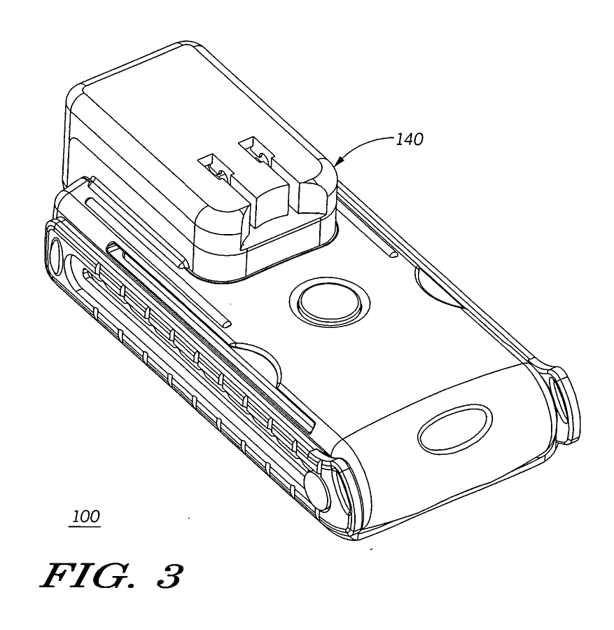

The apparatus 100 can include a casing 110 having a cover portion 120 and a holding portion 130. Further, the casing 110 can also include an integrated charging device 140 (See FIG. 3). Thus, in comparison to existing product offerings, there is no need for purchasing, carrying, and storing a separate charging unit. As discussed above, the casing 110 can include various integrated electronic device components that lesson the user's dependence upon multiple devices. The apparatus 100 including the casing 110 can be constructed of various rigid and semi-rigid materials to protect the electronic host device (not shown) from damage during shipping and for storing in between use. The materials can include any suitable material, such as plastic, and in particular, can include recycled materials. The recycled materials can be obtained from older and discarded electronic devices to prevent those materials from being discarded into landfills. Further, it should be noted that the materials of the apparatus 100 can be selected so that those materials will be readily available to be recycled and used in future apparatuses and devices.

In addition to the holding portion 130 being constructed and arranged to store the electronic host device, the holding portion 130 can also include one or more compartments to hold electronic host device accessories. The compartments can be separate compartments for individual accessories or can be general compartments for multiple accessories. Further, the compartments can have covers for forming enclosures. For instance, the holding portion 130 can include a compartment constructed and arranged to hold an additional battery. Additionally, such a compartment can be communicably coupled to a charging device 140 so that the separate battery can be charged during storage. Other examples of compartments constructed and arranged to hold electronic host device accessories can include an earpiece compartment, an additional antenna compartment, an additional memory compartment, a stylus compartment, and the like. The above list is intended to be merely exemplary and should not be construed to limit the invention.

Still further, in efforts to reduce waste the casing 110 can be constructed and arranged to store any documentation media, such as user guides and/or compact discs containing text, image, or multi-media guides. For instance, a compact disc with a quick instruction diagram printed on its surface can store the more detailed user guide electronically. In that regard, it should be noted that the full volume documentation media can be stored on a medium, such as a flash random access memory device or any other removable (or non-removable) storage medium, that is readable using the electronic host device or possibly the casing itself if the casing includes the requisite functionality (i.e., any presentation device) such as a display. In another alternative arrangement, the full volume documentation can be embedded in electronic memory within the casing and a surface of the casing itself could include an abbreviated instruction manual or quick instruction diagram. In the past, such documentation media was typically discarded by the user, however, in this arrangement, the documentation media can be stored in the casing 110. Thus, the documentation media can be readily and conveniently available for future reference and, therefore, will remain out of landfills.

The cover portion 120 of the casing 110 can include a transparent portion 150 for displaying at least a portion of the electronic device. The transparent portion 150 can be shaped and sized to provide a full view of the electronic host device; however, the invention is not limited in this regard as the transparent portion can be shaped and sized to provide only a partial view of the electronic host device. For instance, the apparatus 100 can be generically designed for use with a plurality of brands where the brand of the electronic host device is displayed via the transparent portion 150. Additionally, the transparent portion 150 can allow customers to view the host device working without exposing the host device to potential customer abuse. Still further, the transparent portion 150 can allow customers to view any documentation media.

The integrated charging device 140 can charge the electronic host device's power supply and can optionally be removable from the housing 110 although it is still considered “integrated” in this instance. Because the charging device 140 is integrated, not only is a separate charging device not needed, the chance of losing or simply forgetting the separate device is eliminated. The charging device 140 can be any suitable device that is known in the art, and can include solar charging elements typically used for trickle charging. Also, it should be noted the charging device 140 can be plugged directly into an outlet in one embodiment.

In one possible embodiment, the combined packaging and storage apparatus can be oriented in a slidable configuration as described herein. The cover portion 120 can be coupled to the holding portion 130 in a variety of arrangements to allow the cover portion 120 to be moved for access to the holding portion 130 and any device therein. The cover portion 120 can be slidably coupled to the holding portion 130 in an arrangement where the cover portion 120 and/or the holding portion 130 includes one or more elongated channels 160. The casing 110 can also include a pin 170 which can extend and traverse through the elongated channel 160 of the cover portion 120. With the pin 170 and the elongated channel 160 of the cover portion 120, the cover portion 120 can slide relative to the holding portion 130. Further, a protrusion (not shown) on the cover portion 120 can engage an elongated channel 160 of the holding portion 130 for stabilizing the sliding movement.

Additionally, the elongated channels 160 can include stops 180 for resisting movement of the cover portion 120 from a rested position. The stops 180 can be bumps and/or apertures that are engaged by a portion of the cover portion 120 or the holding portion 130 to resist movement. Although not shown, the stops 180 can also include securing members, such as locks, for firmly securing the cover portion 120 in a particular position. The stops 180 can therefore be used to maintain the cover portion 120 in a partially open position to prevent unintended closures.

In addition to being slidably coupled, another possible embodiment of the combined packaging and storage apparatus can be oriented in a box and lid configuration as described herein. The cover portion 120 can be removably coupled to the holding portion 130. The pin 170 can be detachable for allowing the cover portion 120 to be removed from the holding portion 130. For instance, the pin 170 can snap fit to the casing 110 allowing for easy attachment and detachment. Once the cover portion 120 is removed, the holding portion 130 can be used as an electronic device stand or as a charging device 140 base.

In yet another possible embodiment, the combined packaging and storage apparatus can be oriented in a hingable configuration as described herein. The cover portion 120 can also be hingably coupled to the holding portion 130 for allowing pivoting of the cover portion 120. The pivoting action can be used to close the cover portion 120, such as in a clam shell design, and can also be used to re-arrange the configuration of casing 110.

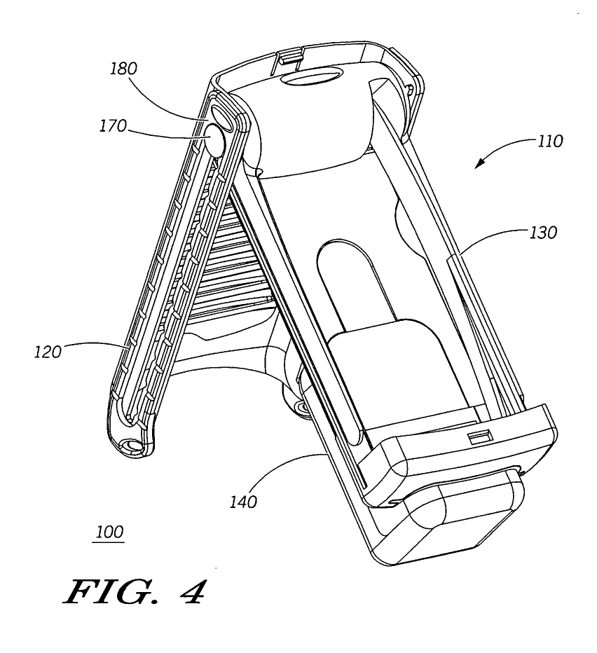

FIG. 4 illustrates another arrangement of apparatus 100. In this arrangement, the casing 110 is shown where the cover portion 120 is supporting the holding portion 130 in a standing position. The stops 180 have engaged the pin 170 to hold the casing 110 in this configuration. Nevertheless, it should be noted that the illustrated configuration is only one of the many available configurations in which the cover portion 120 can support the holding portion. Supporting the holding portion 130 in a standing position can allow the user, or multiple users, to view the electronic host device functioning while charging. For instance, a group of users may gather around the apparatus 100 for viewing content displayed on the screen of the electronic host device or for a conference call.

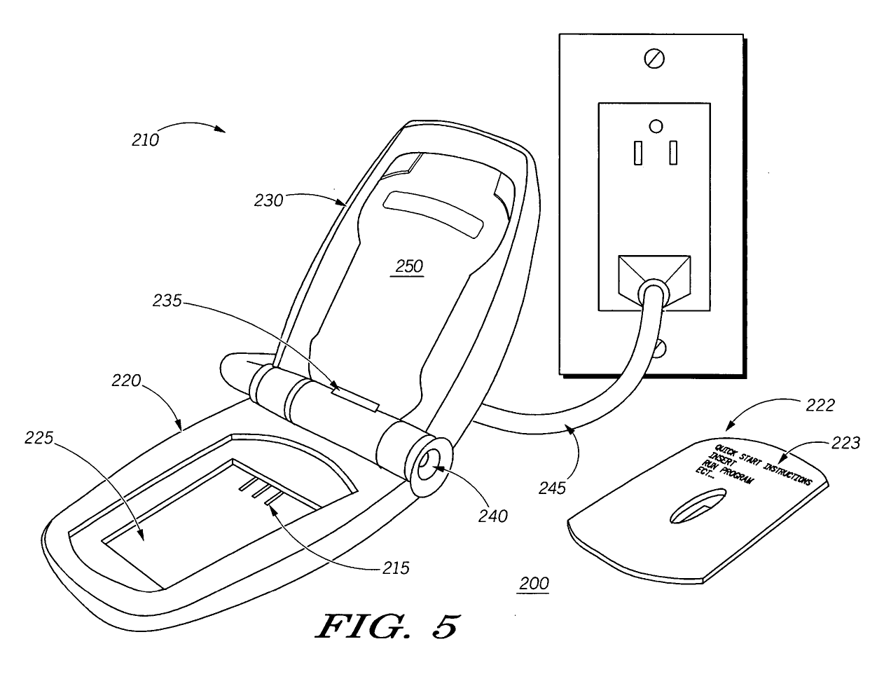

FIG. 5 illustrates another embodiment of an integrated packaging and storage apparatus 200 for an electronic host product or device 250 in accordance with the inventive arrangements. The host product 250 can be any number of devices including, but not limited to a cellular phone, cordless phone, a radio, a personal digital assistant, a shaver, a laptop computer, a smart phone, a camera, a camcorder, a bar-code scanner, a meter measuring device, and a portable medical device.

The apparatus 200 is a multi-purpose product packaging having a casing 210 removably and substantially encasing the electronic host product 250 which already has its own housing. In this embodiment, the casing 210 forms a clam shell where the cover portion 220 is hingably coupled to the holding portion 230. The internal contours of the holding portion 230 can correspond to the shape of the electronic host device so that the device fits securely. The casing 210 can include circuitry 240 for providing at least one secondary function to the electronic host product 250. In this embodiment, the circuitry 240 can be an integrated charging device located at the hingable coupling between portions 220 and 230 and can include a conventional cord or a retractable cord 245.

The casing 210 can include an interface 255 for enabling the at least one secondary function to operate in conjunction with the electronic host product 250. In this embodiment, an integrated charging device within the casing 210 can also include an interface or connector 235 that enables the charging device 240 to couple and charge any battery on the electronic host device 250. Therefore, during transportation, the cord 245 can be retracted into the casing 210 or can otherwise be detached and stored away within a compartment 225 residing within the cover portion 220.

The compartment 225 can also store an additional battery (see FIG. 6) which can optionally be charged via contacts 215 if desired. Further note that the casing 210 can further include a storage medium 222 within the removable casing having an instruction manual stored electronically therein and an abbreviated instruction manual 223 presented on a surface of the casing 210. The storage medium 222 can come in various forms including flash memory or other types of memory embedded permanently or temporarily within the casing 210. In this instance, the storage medium 222 can be a CD-ROM having the full volume instruction manual stored electronically therein and also optionally serving as a cover for the storage compartment 225. The abbreviated instruction manual 223 can be a Quickstart guide printed on the surface of the storage medium 222 which is removable from the casing 210 in this instance.

Note that the circuitry 240 included or integrated with the casing 210 is not necessarily limited to charging circuitry. Other alternative or optional circuitry in the casing 210 can include for example circuitry for solar cell trickle charging, hand-crank charging, induction charging, encryption or decryption, location finding, wireless interconnection, memory, bar code scanning, printing, remote metering, virtual keyboarding, or projection displaying. Further note that the interfaces 255 are certainly not limited to hardware interfaces such as USB ports, Ethernet ports, firewire ports and the like, but may include wireless interconnections such as Bluetooth connections, 802.11 type connections, or 802.16 type connections or any other short range protocol connection or long range protocol connection, such as GSM, CDMA, TDMA, or iDEN protocols.

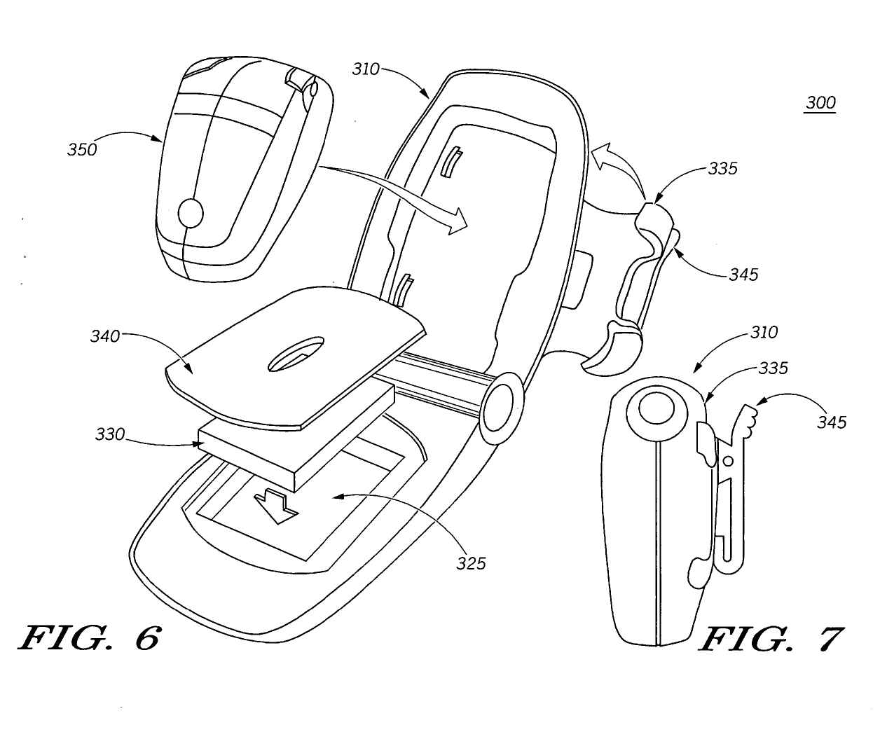

FIGS. 6 and 7 illustrate two vantage points in the form of perspective and side views respectively of another embodiment of an integrated packaging and storage apparatus 300 for an electronic host device 350 in accordance with the inventive arrangements. A casing 310 forming a portion of the apparatus 300 can be constructed and arranged for use with a belt clip 345 so that the belt clip can securely attach to the casing 310. Accordingly, the casing 310 can include an engagement structure 335 for being engaged by the belt clip 345. The engagement structure 335 can be placed the same distance apart that a similar engagement structure on the electronic host device 350 is placed. With this similar geometric relationship, the same belt clip 345 can be used with the electronic host device and separately with the housing 310 (or apparatus 300) as desired. With the belt clip 345 attached to the casing 310, a user can unobtrusively carry the apparatus 300 wherever needed. Further note that the casing 310, as in the casing 210 of FIG. 5, further includes an optional compartment 325 for storing any additional accessories. As shown, the compartment 325 can store a spare battery 330 that can be hidden or substantially hidden from view using a storage medium 340, such as a CD-ROM, for the compartment 325.

This invention can be embodied in other forms without departing from the spirit or essential attributes thereof. For instance, although the electronic device is shown as a mobile phone, one skilled in the art would readily recognize that the invention can be used with a wide variety of electronic devices, such as radios, personal digital assistants, micro computers, and the like. Accordingly, reference should be made to the following claims, rather than to the foregoing specification, as indicating the scope of the invention.

1. A packaging and storage apparatus for electronic devices, comprising:
a casing constructed and arranged to store an electronic host device having its own casing, wherein the apparatus casing provides product packaging used in the process of selling the electronic device and a storage container for the electronic device; and
circuitry within the casing for providing additional functionality for the electronic host device.

2. The apparatus according to claim 1, wherein the packaging and storage apparatus substantially reduces the need for packaging.

3. The apparatus according to claim 1, wherein the apparatus casing includes a cover portion and a holding portion and wherein the cover portion is at least one of removably coupled to the holding portion, slidably coupled to the holding portion, hingably coupled to the holding portion, snapably coupled to the holding portion, or a combination thereof.

4. The apparatus according to claim 1, wherein the apparatus further comprises a removable storage medium having an instruction manual stored electronically therein and an abbreviated instruction manual presented on a surface of the removable storage medium.

5. The apparatus according to claim 3, wherein at least one of the cover portion and the holding portion includes an elongated channel allowing relative sliding movement.

6. The apparatus according to claim 5, wherein the elongated channel includes stops.

7. The apparatus according to claim 3, wherein the cover portion supports the holding portion in a standing position.

8. The apparatus according to claim 3, wherein the holding portion includes separate compartments constructed and arranged to hold electronic host device accessories.

9. The apparatus according to claim 1, wherein the casing includes electronic device components communicably coupled to the electronic host device.

10. The apparatus according to claim 1, wherein a portion of the apparatus casing is comprised of recycled materials.

11. The apparatus according to claim 1, wherein the charging device includes at least one of a wireless charging device and a charging device with a retractable wire.

12. The apparatus according to claim 1, wherein the apparatus casing includes a belt clip engagement structure.

13. The apparatus according to claim 12, wherein the engagement structure is constructed and arranged so that a belt clip attaches to the apparatus casing.

14. A multi-purpose product packaging for an electronic host product having its own casing, comprising:
a casing for removably and substantially encasing the electronic host product;
circuitry within the casing for providing at least one function to the electronic host product; and
an interface integrated with the casing for enabling the at least one function to operate in conjunction with the electronic product.

15. The multi-purpose product packaging of claim 14, wherein the circuitry providing the at least one function is selected from the group of battery charging circuitry, solar cell trickle charging circuitry, hand-crank charging circuitry, induction charging circuitry, encryption or decryption circuitry, location finding circuitry, wireless interconnection circuitry, memory circuitry, bar code scanning circuitry, printing circuitry, remote metering circuitry, virtual keyboard projection circuitry, or projection display circuitry.

16. The multi-purpose product packaging of claim 14, wherein the product packaging is arranged and constructed in the form of a clam-shell product enclosure.

17. The multi-purpose product packaging of claim 14, wherein the electronic product is selected from the group of portable electronic products comprising a cellular phone, cordless phone, a radio, a personal digital assistant, a shaver, a laptop computer, a smart phone, a camera, a camcorder, a bar-code scanner, a meter measuring device, and a portable medical device.

18. The multi-purpose product packaging of claim 14, wherein the interface is selected from the group comprising a hardware port such as a USB port, an Ethernet port, a firewire port, or a wireless interconnection such as Bluetooth connections, 802.11 type connections, and 802.16 type connections.

19. The multi-purpose product packaging of claim 14, wherein the apparatus casing is at least partially made from recyclable material.

20. A multi-purpose product packaging for an electronic host product having its own casing, comprising:
a removable casing for selectively encasing the electronic host product, wherein the removable casing is at least partially made from recyclable material;
circuitry within the casing for providing at least a secondary electronic function, such circuitry comprising an interface enabling the secondary electronic function to operate in conjunction with the electronic product.

21. A multi-purpose product packaging for an electronic host product having its own casing, comprising:
a removable casing for selectively encasing the electronic host product; and
a storage medium within the removable casing having an instruction manual stored electronically therein and an abbreviated instruction manual presented on a surface of the storage medium.

22. The multi-purpose product packaging of claim 21, wherein the abbreviated instruction manual is a QuickStart guide printed on the surface of the storage medium which is removable from the removable casing.

23. The multi-purpose product packaging of claim 21, wherein the multi-purpose product packaging further comprises circuitry within the removable casing for providing at least a secondary electronic function, such circuitry comprising an interface enabling the secondary electronic function to operate in conjunction with the electronic host product.
